(19) United States
(12) Patent Application Publication
(10) Pub. No.: US 2014/0295580 A1
(43) Pub. Date: Oct. 2, 2014

(54) METHOD FOR MANUFACTURING SEMICONDUCTOR DEVICE AND MANUFACTURING APPARATUS

(71) Applicant: Tokyo Electron Limited, Minato-ku (JP)

(72) Inventor: Kenichi HARA, Tsukuba city (JP)

(73) Assignee: Tokyo Electron Limited, Minato-ku (JP)

(21) Appl. No.: 14/242,240

(22) Filed: Apr. 1, 2014

(30) Foreign Application Priority Data
Apr. 2, 2013 (JP) 2013-077142
Mar. 28, 2014 (JP) 2014-068801

(51) Int. Cl. H01L 43/12; H01L 43/02

(52) U.S. Cl. CPC H01L 43/12; H01L 43/02
USPC 438/3; 156/345.1; 156/345.52

(57) ABSTRACT

A method for manufacturing a semiconductor device includes accommodating in a processing chamber a semiconductor structural body having a semiconductor substrate and a laminated structure formed on the semiconductor substrate and having multiple metal films including a noble-metal film, and generating a bias voltage on the semiconductor substrate while generating an oxygen plasma in the processing chamber such that a plasma treatment removes at least part of the noble-metal film in the laminated structure of the semiconductor structural body.

### CROSS REFERENCE TO RELATED APPLICATIONS

The present application is based upon and claims the benefit of priority to Japanese Patent Application No. 2013-077142, filed Apr. 2, 2013, and Japanese Patent Application No. 2014-068801, filed Mar. 28, 2014. The entire contents of these applications are incorporated herein by reference.

### BACKGROUND OF THE INVENTION

1. Field of the Invention

The present invention relates to a method for manufacturing a semiconductor device having a noble-metal film and to an apparatus for manufacturing the same.

2. Description of Background Art

In recent years, MRAM (Magnetoresistive Random Access Memory) has been developed as a next-generation nonvolatile memory to replace DRAM and SPRAM. MRAM has an MTJ (Magnetic Tunnel Junction) element instead of a capacitor and stores data using magnetic states.

### SUMMARY OF THE INVENTION

According to one aspect of the present invention, a method for manufacturing a semiconductor device includes accommodating in a processing chamber a semiconductor structural body having a semiconductor substrate and a laminated structure formed on the semiconductor substrate and having multiple metal films including a noble-metal film, and generating a bias voltage on the semicondutor substrate while generating an oxygen plasma in the processing chamber such that a plasma treatment removes at least part of the noble-metal film in the laminated structure of the semiconductor structural body.

According to another aspect of the present invention, an apparatus for manufacturing a semiconductor device includes a processing chamber which accommodates a semiconductor structural body having a semiconductor substrate and a laminated structure formed on the semiconductor substrate and having multiple metal films including a noble-metal film, an oxygen-plasma generating device which generates an oxygen plasma in the processing chamber, and a bias-voltage generating device which generates a bias voltage on the semiconductor substrate in the processing chamber. The oxygen-plasma generating device and the bias-voltage generating device are structured such that the bias-voltage generating device generates the bias voltage on the semiconductor substrate while the oxygen-plasma generating device generates the oxygen plasma in the processing chamber and that a plasma treatment removes at least part of the noble-metal film in the laminated structure of the semiconductor structural body.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 is a cross-sectional view schematically showing the structure of an apparatus for manufacturing a semiconductor device according to an embodiment of the present invention;

FIGS. 2(A)-2(D) show processing steps to illustrate a mechanism for removing a noble-metal film according to an embodiment;

FIGS. 3(A)-3(D) show processing steps of a method for manufacturing a semiconductor device according to an embodiment; and

FIG. 4 is a cross-sectional view schematically showing the structure of an MRAM.

### DETAILED DESCRIPTION OF THE EMBODIMENTS

The embodiments will now be described with reference to the accompanying drawings, wherein like reference numerals designate corresponding or identical elements throughout the various drawings.

First, a description is provided for an apparatus for manufacturing a semiconductor device according to an embodiment of the present invention.

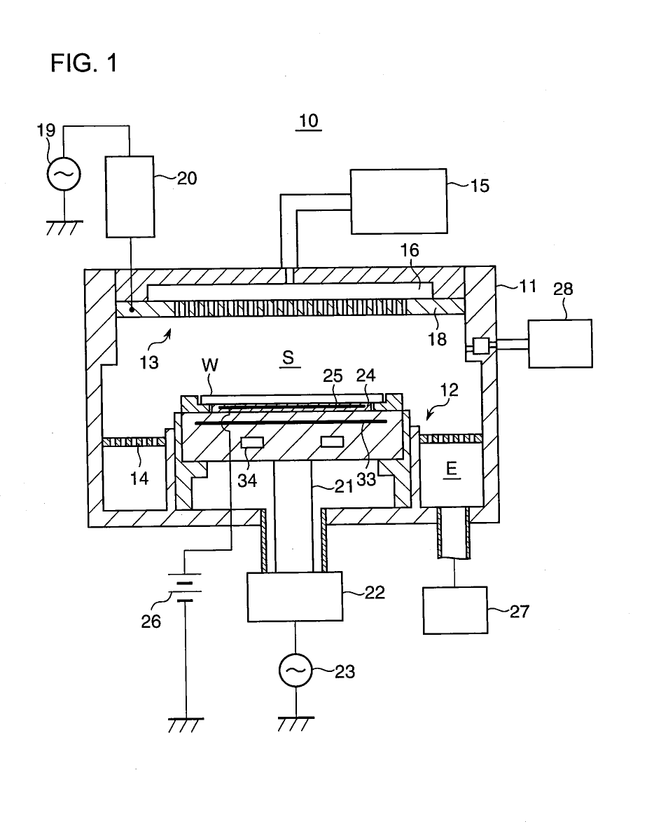

FIG. 1 is a cross-sectional view schematically showing the structure of an apparatus for manufacturing a semiconductor device according to the present embodiment.

In FIG. 1, as an apparatus for manufacturing a semiconductor device, parallel-plate plasma processing apparatus 10 is provided with substantially cylindrical chamber 11 (processing chamber); stage-type susceptor 12 positioned in the lower part of chamber 11 and for mounting a semiconductor wafer (hereinafter simply referred to as a “wafer”) (W) at its top; showerhead 13 positioned in the upper part of chamber 11 to face susceptor 12; and ring-shaped exhaust plate 14 positioned to surround the side surface of susceptor 12.

Exhaust plate 14 is made of an annular member having numerous gas passage holes penetrating in a thickness direction, and vertically divides chamber 11 into two sections—processing space (S) and exhaust space (manifold) (E).

Showerhead 13 has a built-in buffer 16 that is connected to processing-gas supply unit 15, and also has disc-shaped electrode plate 18 that separates buffer 16 and processing space (S). Electrode plate 18 is positioned to cover the entire surface of a wafer (W) mounted on susceptor 12. In addition, first high-frequency power source 19 is connected to electrode plate 18 through first matching device 20, and first high-frequency power source 19 provides electrode plate 18 with high-frequency power at a relatively high frequency for generating plasma. Electrode plate 18 to which high-frequency power for generating plasma is supplied works as an upper electrode for applying high-frequency power to processing space (S).

Electrode plate 18 also has numerous gas supply holes penetrating in a thickness direction, through which a processing gas such as a mixed gas of oxygen gas and argon gas supplied to buffer 16 by processing-gas supply unit 15 is introduced into processing space (S). Since numerous gas supply holes of electrode plate 18 are distributed so as to cover the entire surface of a wafer (W) mounted on susceptor 12, the processing gas is dispersed in processing space (S) to cover the entire surface of the wafer (W).

Second high-frequency power source 23 is connected to susceptor 12 through supply rod 21 and second matching device 22, and second high-frequency power source 23 provides susceptor 12 with high-frequency power at a relatively low frequency for applying a bias voltage. In addition, susceptor 12 facing electrode plate 18 of showerhead 13 works as a lower electrode.

In the upper part of susceptor 12, electrostatic chuck (ESC) 24 made of a dielectric disk is positioned, and electrode plate 25 is built into electrostatic chuck 24. DC power source 26 is connected to electrode plate 25. When DC voltage is applied to electrode plate 25, electrostatic chuck 24 uses static power to suction-hold the wafer (W) mounted on susceptor 12. Also, heater 33 for applying heat to a mounted wafer and coolant channel 34 to cool the wafer (W) are built into susceptor 12.

Exhaust space (E) is connected to exhaust unit 27. Exhaust unit 27 decompresses processing space (S) through exhaust space (E) and subsequently through exhaust plate 14.

In addition, organic-acid supply unit 28 (organic-acid supply component) is positioned in the vicinity of chamber 11 to be connected to processing space (S) and to supply processing space (S) with a gas of organic-acid having a carboxyl group, such as acetic acid and hfac (hexafluoroacetylacetone).

In plasma processing apparatus 10, when plasma treatment is performed on a wafer (W), processing space (S) is decompressed, and a processing gas is introduced into processing space (S) while high-frequency power is applied to electrode plate 18 so as to generate an electric field in processing space (S). The processing gas introduced into processing space (S) is excited by the electric field and generates plasma. The cations in the plasma are drawn through susceptor 12 to the wafer (W) by a bias voltage generated on the wafer (W), and plasma treatment is performed on the wafer (W). Also, the radicals in the plasma reach the wafer (W) and conduct plasma treatment on the wafer (W).

In plasma processing apparatus 10, since electrode plate 18 is positioned to cover the entire surface of a wafer (W) and numerous gas-supply holes of electrode plate 18 are distributed so as to cover the entire surface of a wafer (W) as described above, plasma is generated to cover the entire surface of the wafer (W), and the generated plasma uniformly conducts plasma treatment on the entire surface of the wafer (W).

When plasma processing apparatus 10 performs plasma treatment on a wafer (W), operation of each device in plasma processing apparatus 10 is controlled by a control unit (not shown) according to a predetermined program.

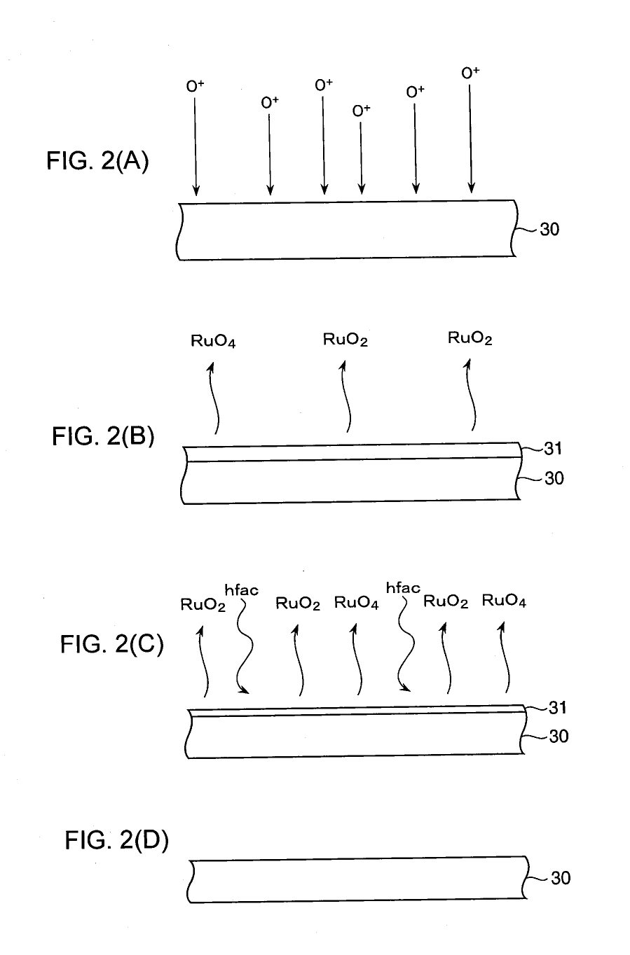

FIG. 2 shows processing steps to illustrate a mechanism for removing a noble-metal film in the present embodiment.

First, after an oxygen plasma is generated, a bias voltage is generated on a wafer (W) where Ru film 30 as a noble-metal film is formed, oxygen cations (O⁺) in the oxygen plasma are bombarded at Ru film 30. Namely, instead of RIE (Reactive Ion Etching), etching is conducted on Ru film 30 through sputtering using the oxygen plasma (FIG. 2(A)).

Since Ru film 30 is hard to etch, it is not easy to physically etch Ru film 30 with bombarded oxygen cations. The kinetic energy of the bombarded oxygen cations causes chemical reactions in the oxygen cations and Ru film 30, and the surface of Ru film 30 is oxidized so as to form oxide film 31 made of RuO₄ and RuO₂, for example. Since an oxide of a noble-metal film is generally unstable and has a low vapor pressure, it tends to sublime. Thus, in the present embodiment, sublimation of oxide film 31 is facilitated by applying heat to a wafer (W) (FIG. 2(B)). At that time, it is preferred to heat the wafer (W) at room temperature (20° C., for example) or higher, and at the Curie temperature (30° C., for example) or lower.

In addition, an organic acid having a carboxyl group is capable of easily decomposing and removing a metal oxide. Thus, in the present embodiment, removing oxide film 31 may be facilitated by supplying an acetic-acid gas or hfac gas toward Ru film 30 (FIG. 2(C)).

Oxide film 31 is securely removed by heating a wafer (W) or supplying an hfac gas or the like as described above (FIG. 2(D)).

In FIG. 2, Ru film 30 remains after the removal of oxide film 31, but the entire Ru film 30 can be changed to oxide film 31 by adjusting the time for bombarding oxygen cations and the level of bias voltage. Accordingly, Ru film 30 is entirely removed when oxide film 31 is removed.

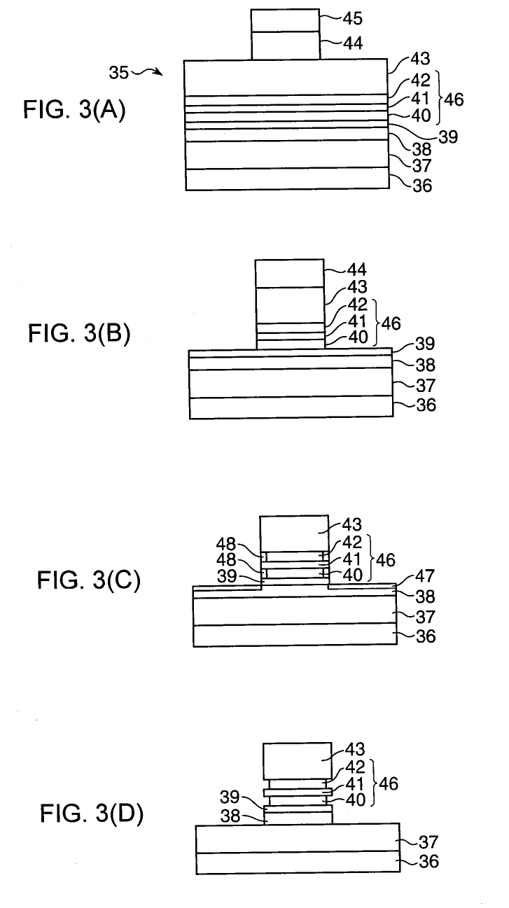

FIG. 3 shows processing steps of a method for manufacturing a semiconductor device according to an embodiment.

First, a wafer (W), on which laminated structure 35 of an MRAM as a semiconductor device is formed using a CVD deposition apparatus or the like, is loaded into chamber 11 and mounted on susceptor 12.

On an oxide film such as SiO₂ film (not shown) of a wafer (W), laminated structure 35 has Ta film 36, PtMn film 37, CoFe film 38, Ru film 39 (noble-metal film),

CoFeB film 40, MgO film 41, CoFeB film 42, Ta film 43, SiO₂ film 44 and SiN film 45 deposited in that order from the bottom (FIG. 3(A)).

Ta film 43, SiO₂ film 44 and SiN film 45 are hard masks, and SiO₂ film 44 and SiN film 45 are formed in a desired pattern by lithography using a photoresist film or the like. In addition, CoFeB film 40, MgO film 41 and CoFeB film 42 form MTJ element 46.

First, a plasma is generated in chamber 11 from a processing gas such as a C₅F₈ gas, and using SiO₂ film 44 and SiN film 45 as hard masks, portions of Ta film 43, CoFeB film 42, MgO film 41 and CoFeB film 40 that are not covered by SiO₂ film 44 and the like are etched away by RIE so that Ru film 39 is exposed. At that time, SiN film 45 is also gradually etched by the plasma and disappears (FIG. 3(B)).

Next, in chamber 11, the plasma is generated from a mixed gas of oxygen gas and argon gas containing oxygen gas at 10% to 50%, and high-frequency power for applying a bias voltage is also supplied to susceptor 12 from second high-frequency power source 23 so as to generate a bias voltage on a wafer (W) through susceptor 12. Using SiO₂ film 44 and Ta film 43 as hard masks, oxygen cations in the oxygen plasma are bombarded at portions of Ru film 39 not covered by Ta film 43 and the like (hereinafter referred to as an “exposed portion”). In addition, the wafer (W) is heated by heater 33 of susceptor 12 (plasma treatment step).

In the above step, oxygen cations and Ru film 30 are chemically reacted as described with reference to FIG. 2(B), and oxide film 31 made of RuO₄ and RuO₂ is formed. During that time, the time for bombarding oxygen cations and the level of bias voltage are adjusted so that the exposed portion of Ru film 39 is entirely changed to oxide film 31. Also, since the wafer (W) is heated, the sublimation of oxide film 31 is accelerated and the film is removed. As a result, the exposed portion of Ru film 39 is removed.

In the present embodiment, to securely remove the exposed portion of Ru film 39, bombarding oxygen cations is continued longer than the required time for removing the exposed portion of Ru film 39. Thus, the surface of the exposed portion of CoFe film 38 is also oxidized to form oxide film 47. In addition, SiO₂ film 44 is also gradually etched by the plasma and disappears (FIG. 3(C)).

When the oxygen plasma is generated, since side surfaces of MTJ element 46 are exposed as shown in FIG. 3(B), oxide film 48 is formed in the exposed portions of CoFeB films (40, 42), which are magnetic films of MTJ element 46. If even part of the magnetic film is oxidized, the performance of MTJ element 46 is lowered. Thus, after the oxygen plasma has been removed or has disappeared following the removal of Ru film 30, the wafer (W) is heated to 200° C. to 300° C. by heater 33 while an hfac gas is introduced from organic-acid supply unit 28 into chamber 11 to decompose oxide film 48 by hfac so that the film is removed (organic-acid treatment step). During that time, oxide film 47 of CoFe film 38 is also removed.

Next, a plasma is generated in chamber 11 from a processing gas such as argon gas and chlorine gas, and the exposed portion of CoFe film 38 is etched by RIE using Ta film 43 as a hard mask so that PtMn film 37 is exposed, thereby completing the present method.

According to the method for manufacturing a semiconductor device shown in FIG. 3, when removing the exposed portion of Ru film 39 from laminated structure 35, an oxygen plasma is generated in chamber 11 while a bias voltage is generated on a wafer (W) and heat is further applied on the wafer (W). Oxygen cations are bombarded at Ru film 39 where a bias voltage is generated, and Ru film 39 is oxidized by the kinetic energy of the oxygen cations. Since an oxide of Ru film 39 is unstable and easy to sublime, the oxide is easily removed by being sublimed by the heat applied to the wafer (W).

Also, according to the method for manufacturing a semiconductor device shown in FIG. 3, it is not necessary to use a mixed gas containing halogen as a processing gas, thereby eliminating a cleaning step for removing the halogen.

Moreover, by employing a widely used parallel-plate plasma processing apparatus, it is easy to generate a bias voltage and to generate widely dispersed oxygen plasma in chamber 11. Thus, Ru film 39 is efficiently etched while eliminating the necessity of using an ion milling apparatus or high-energy plasma to etch Ru film 39. Accordingly, Ru film 39 is etched at low cost without affecting other films of laminated structure 35.

In the method for manufacturing a semiconductor device described above with reference to FIG. 3, an hfac gas is supplied in chamber 11 after the oxygen plasma has been removed or has disappeared, and the hfac is prevented from being burned by the oxygen plasma. In addition, since the wafer (W) is heated to 200° C. to 300° C. when the hfac gas is supplied, removal of oxide film 48 of CoFeB films (40, 42) by hfac is facilitated. When a semiconductor device contains a magnetic film as in the aforementioned laminated structure 35, the temperature of heating a wafer (W) is preferred to be set at or lower than the Curie temperature of the magnetic film.

In the method for manufacturing a semiconductor device described above with reference to FIG. 3, when an oxygen plasma is generated in chamber 11, a mixed gas containing an oxygen gas at 10% to 50% is supplied in chamber 11. Thus, an oxygen plasma is sufficiently generated and oxidation of Ru film 39 is securely carried out by oxygen cations.

In the method for manufacturing a semiconductor device described above with reference to FIG. 3, oxide film 31 is totally sublimed by heating a wafer (W). However, as described with reference to FIG. 2(C), an acetic-acid gas or hfac gas may also be supplied to remove oxide film 31. In such a case as well, acetic acid or hfac is supplied in chamber 11 after the oxygen plasma generated in FIG. 3(C) has been removed or has disappeared.

So far, the present invention has been described using the aforementioned embodiments. However, the present invention is not limited to the embodiments above.

For example, in the method for manufacturing a semiconductor device shown in FIG. 3, oxygen gas (O₂ gas) is listed as a gas for generating an oxygen plasma; however, carbon monoxide gas (CO gas), carbon dioxide gas (CO₂ gas) and hydrogen-peroxide gas (H₂O₂ gas), for example, may also be used as a gas for generating an oxygen plasma.

In addition, in the method for manufacturing a semiconductor device shown in FIG. 3, after the oxygen plasma has been removed or has disappeared, an hfac gas is supplied in chamber 11. However, instead of an hfac gas, an acetic-acid gas may be supplied. Since acetic acid has a smaller molecular weight and is hard to adsorb on a high-temperature wafer (W), the wafer (W) is preferred to be heated at 200° C. or lower by heater 33. Accordingly, acetic acid is securely adsorbed onto the wafer (W), thereby securely removing oxide film 48 of CoFeB film (40, 42). Also, when heating a wafer (W) at 200° C. or lower, laser light is preferred to be irradiated at the wafer (W). By doing so, since the energy of laser light is applied to the wafer (W), especially to oxide film 48, removal of oxide film 48 by acetic acid is facilitated without heating the wafer (W) at 200° C. or higher.

Also, the method for manufacturing a semiconductor device shown in FIG. 3 is applicable to manufacturing an MRAM having a structure other than laminated structure 35 as long as a noble-metal layer is present. Moreover, the above method is applicable not only to an MRAM, but also to a magnetic device having a noble-metal layer, for example, a magnetic head for reading a hard disk. In such a case, the noble-metal layer is not limited to being made of Ru, but may be made of other noble metals such as Pt.

Moreover, when the noble-metal layer is formed above the MTJ element, since the side surfaces of the MTJ element are not exposed to an oxygen plasma and an oxide film is not formed on the CoFeB film of the MTJ element, it is not necessary to supply an hfac gas in chamber 11 after the noble-metal layer is etched.

Furthermore, although the method for manufacturing a semiconductor device shown in FIG. 3 is conducted by a parallel-plate plasma processing apparatus 10, the method may also be conducted by a plasma processing apparatus where a plasma is generated to cover a wide range, for example, an inductively coupled plasma apparatus or a microwave-excited high-density plasma processing apparatus.

The objective of an embodiment according to the present invention may also be achieved when a memory medium that stores the program code of a software to implement the functions of the aforementioned embodiments is supplied to a computer, for example, to a control unit, and when the CPU of the control unit reads the program code stored in the memory medium and executes the program.

In such a case, the program code which was read from the memory medium implements the functions of the aforementioned embodiments, and the program code and the memory medium that stores the program code form an embodiment of the present invention.

Examples of a memory medium to supply a program code are those capable of storing the aforementioned program code such as RAM, NVRAM, Floppy (registered mark) disk, hard disk, optomagnetic disk, optodiscs such as CD-ROM, CD-R, CD-RW and DVD (DVD-ROM, DVD-RAM, DVD-RW, DVD+RW), magnetic tape, nonvolatile memory cards, and other ROMs. Alternatively, the program code may also be supplied to a control unit by downloading the code from other computers and data bases (not shown in the drawings) connected to the Internet, commercial networks or local area networks.

Also, the above embodiments include situations when the functions of the embodiments above are implemented by executing the program code which is read by a control unit, as well as when the operating system running on the CPU executes part or all of the processing based on the instructions in the program code so that the functions of the embodiments above are implemented by such a process.

Furthermore, the above embodiments include the following situations: after the program code read from the memory medium is written on the memory provided in a function expansion board inserted into a control unit or a function expansion unit connected to the control unit, the CPU or the like provided in the function expansion board or the function expansion unit executes part or all of the actual processing based on the instructions in the program code so that the functions of the aforementioned embodiments are implemented by such processing.

The program code above may be in a mode such as an object code, program code executed by an interpreter, script data supplied to the OS or the like.

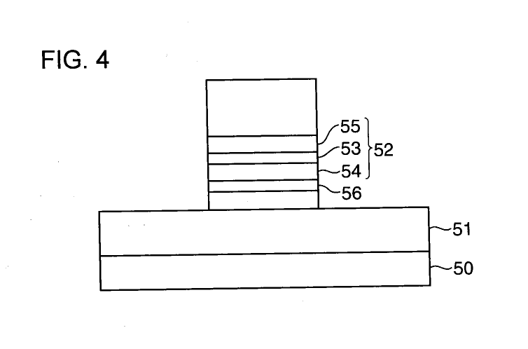

As shown in FIG. 4, an MRAM has Ta film 50 which forms the lower electrode, PtMn film 51 which is a magnetic film, and MTJ element 52. MTJ element 52 is made up of an insulative film such as MgO film 53, and two intense magnetic films such as CoFeB films (54, 55) positioned opposite each other by sandwiching the MgO film, and a noble-metal film such as Ru film 56 is usually disposed between PtMn film 51 and MTJ element 52.

An MRAM is formed by laminating each film by sputtering or the like, and by etching the films using a lithography technique. Since noble-metal films are generally hard to etch, Ru film 56 is etched by physical etching through sputtering in which bias voltage is generated on a semiconductor wafer where MRAMs are to be formed, and the bias voltage causes ions in the plasma to be drawn to the semiconductor wafer.

To conduct such physical etching through sputtering, a so-called ion milling apparatus (for example, see Laid-open Japanese Patent Publication 2005-243420) may be used. The entire contents of this publication are incorporated herein by reference.

In addition, since Ru film 56 can also be etched using high-energy plasma, an RIE (Reactive Ion Etching) apparatus may be used instead of an ion milling apparatus.

Since an ion milling apparatus is used for forming a magnetic head for reading a hard disk, it is difficult to generate a plasma covering a wide range, and it is also difficult to conduct uniform etching on Ru film 56 of numerous MRAMs formed on the entire surface of a semiconductor wafer, whose diameter has been enlarging in recent years. Moreover, an ion milling apparatus requires a grid member to accelerate ions. Since such grid members wear out, using an ion milling apparatus is more costly.

In addition, using a high-energy plasma, it is difficult to secure the etch selectivity of Ru film 56 and other metal films, and, in addition to Ru film 56, other metal films may also be etched.

A method for manufacturing a semiconductor device according to an embodiment of the present invention and an apparatus for manufacturing a semiconductor device according to another embodiment of the present invention are low-cost, and the noble-metal film is etched without affecting other metal films in the semiconductor device.

A method for manufacturing a semiconductor device according to an embodiment of the present invention is such a method to manufacture a semiconductor device having a laminated structure which is formed on a semiconductor substrate accommodated in a processing chamber and which has multiple metal films including at least a noble-metal film. The method is characterized by including a plasma processing step in which an oxygen plasma is generated in the processing chamber, while a bias voltage is generated on the semiconductor substrate, when removing at least part of the noble-metal film.

A method for manufacturing a semiconductor device according to another embodiment of the present invention is characterized by heating the semiconductor substrate in the plasma processing step.

A method for manufacturing a semiconductor device according to yet another embodiment of the present invention is characterized by further including, subsequent to the plasma processing step, an organic-acid processing step in which an organic acid containing a carboxyl group is supplied into the processing chamber.

In a method for manufacturing a semiconductor device according to yet another embodiment of the present invention, the organic acid is acetic acid or hfac.

A method for manufacturing a semiconductor device according to yet another embodiment of the present invention is characterized by heating the semiconductor substrate at 200° C. to 300° C. when the organic acid is hfac.

A method for manufacturing a semiconductor device according to yet another embodiment of the present invention is characterized by heating the semiconductor substrate at 200° C. or lower when the organic acid is acetic acid.

A method for manufacturing a semiconductor device according to yet another embodiment of the present invention is characterized by irradiating laser light at the semiconductor substrate when heating the semiconductor substrate at 200° C. or lower.

A method for manufacturing a semiconductor device according to yet another embodiment of the present invention is characterized by the semiconductor device further having an MTJ element.

A method for manufacturing a semiconductor device according to yet another embodiment of the present invention is characterized by supplying in the processing chamber a mixed gas containing an oxygen gas at 10% to 50% when the plasma processing step is conducted.

An apparatus for manufacturing a semiconductor device according to yet another embodiment of the present invention has a processing chamber that accommodates a semiconductor substrate on which to form a semiconductor device having a laminated structure made of multiple metal films including at least a noble-metal film, and an oxygen plasma is generated in the chamber. When removing at least part of the noble-metal film, an oxygen plasma is generated in the processing chamber while a bias voltage is generated on the semiconductor substrate.

An apparatus for manufacturing a semiconductor device according to yet another embodiment of the present invention is characterized by heating the semiconductor substrate when an oxygen plasma is generated in the processing chamber.

An apparatus for manufacturing a semiconductor device according to yet another embodiment of the present invention is characterized by further having an organic-acid supply device to supply to the processing chamber an organic acid having a carboxyl group.

According to yet another embodiment of the present invention, in a method for manufacturing a semiconductor device formed on a semiconductor substrate accommodated in a processing chamber and having a laminated structure made of multiple metal films including at least a noble-metal film, an oxygen plasma is generated in the processing chamber while a bias voltage is generated on the semiconductor substrate when removing at least part of the noble-metal film. Ions in the oxygen plasma are bombarded at the noble-metal film with a bias voltage generated thereon, and the noble metal is oxidized by the energy of the ions. Since an oxide of the noble metal is unstable, it is easily removed through sublimation. Also, since generating a bias voltage and an oxygen plasma covering a wide range in the processing chamber is easily achieved by using a widely employed parallel-plate plasma processing apparatus, the necessity of using an ion milling apparatus or high-energy plasma is eliminated, thereby resulting in etching the noble metal at low cost without affecting other metal films in the semiconductor device.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a semiconductor device, comprising:
accommodating in a processing chamber a semiconductor structural body having a semiconductor substrate and a laminated structure formed on the semiconductor substrate and comprising a plurality of metal films including a noble-metal film; and
generating a bias voltage on the semiconductor substrate while generating an oxygen plasma in the processing chamber such that a plasma treatment removes at least a portion of the noble-metal film in the laminated structure of the semiconductor structural body.

2. A method for manufacturing a semiconductor device according to claim 1, wherein the plasma treatment includes heating the semiconductor substrate.

3. A method for manufacturing a semiconductor device according to claim 1, further comprising:
supplying an organic acid having a carboxyl group into the processing chamber subsequent to the plasma treatment such that the organic acid applies an organic-acid treatment to the semiconductor structural body.

4. A method for manufacturing a semiconductor device according to claim 2, further comprising:
supplying an organic acid having a carboxyl group into the processing chamber subsequent to the plasma treatment such that the organic acid applies an organic-acid treatment to the semiconductor structural body.

5. A method for manufacturing a semiconductor device according to claim 3, wherein the organic acid is acetic acid or hfac.

6. A method for manufacturing a semiconductor device according to claim 4, wherein the organic acid is acetic acid or hfac.

7. A method for manufacturing a semiconductor device according to claim 3, wherein the organic acid is hfac, and the organic-acid treatment includes heating the semiconductor substrate at a temperature in a range of 200° C. to 300° C.

8. A method for manufacturing a semiconductor device according to claim 4, wherein the organic acid is acetic acid, and the organic-acid treatment includes heating the semiconductor substrate at a temperature of 200° C. or lower.

9. A method for manufacturing a semiconductor device according to claim 8, wherein the heating of the semiconductor substrate comprises irradiating laser upon the semiconductor substrate such that the semiconductor substrate is heated at the temperature of 200° C. or lower.

10. A method for manufacturing a semiconductor device according to claim 1, wherein the semiconductor structural body has an MTJ element.

11. A method for manufacturing a semiconductor device according to claim 1, wherein the plasma treatment includes supplying in the processing chamber at least one of O₂ gas, CO gas, CO₂ gas and H₂O₂ gas.

12. A method for manufacturing a semiconductor device according to claim 2, wherein the plasma treatment includes supplying in the processing chamber at least one of O₂ gas, CO gas, CO₂ gas and H₂O₂ gas.

13. A method for manufacturing a semiconductor device according to claim 3, wherein the plasma treatment includes supplying in the processing chamber at least one of O₂ gas, CO gas, CO₂ gas and H₂O₂ gas.

14. A method for manufacturing a semiconductor device according to claim 11, wherein the plasma treatment includes supplying in the processing chamber a mixed gas including the O₂ gas in an amount of 10% to 50%.

15. A method for manufacturing a semiconductor device according to claim 12, wherein the plasma treatment includes supplying in the processing chamber a mixed gas including the O₂ gas in an amount of 10% to 50%.

16. A method for manufacturing a semiconductor device according to claim 13, wherein the plasma treatment includes supplying in the processing chamber a mixed gas including the O₂ gas in an amount of 10% to 50%.

17. An apparatus for manufacturing a semiconductor device, comprising:
a processing chamber configured to accommodate a semiconductor structural body having a semiconductor substrate and a laminated structure formed on the semiconductor substrate and comprising a plurality of metal films including a noble-metal film;
an oxygen-plasma generating device configured to generate an oxygen plasma in the processing chamber; and
a bias-voltage generating device configured to generate a bias voltage on the semiconductor substrate in the processing chamber,
wherein the oxygen-plasma generating device and the bias-voltage generating device are configured such that the bias-voltage generating device generates the bias voltage on the semiconductor substrate while the oxygen-plasma generating device generates the oxygen plasma in the processing chamber and that a plasma treatment removes at least a portion of the noble-metal film in the laminated structure of the semiconductor structural body.

18. An apparatus for manufacturing a semiconductor device according to claim 17, further comprising:
a semiconductor substrate heating device configured to heat the semiconductor substrate when the oxygen plasma is generated in the processing chamber.

19. An apparatus for manufacturing a semiconductor device according to claim 17, further comprising:
an organic-acid supply device configured to supply into the processing chamber an organic acid having a carboxyl group.

20. An apparatus for manufacturing a semiconductor device according to claim 18, further comprising:
an organic-acid supply device configured to supply into the processing chamber an organic acid having a carboxyl group.
